(19) United States
(12) Patent Application Publication
(10) Pub. No.: US 2025/0215207 A1
(43) Pub. Date: Jul. 3, 2025

(54) RESIN COMPOSITION FOR FORMING PHASE-SEPARATED STRUCTURE AND METHOD FOR PRODUCING STRUCTURE HAVING PHASE-SEPARATED STRUCTURE

(71) Applicant: TOKYO OHKA KOGYO CO., LTD., Kawasaki-shi (JP)

(72) Inventors: Shota IINO, Kawasaki-shi (JP); Junichi TSUCHIYA, Kawasaki-shi (JP)

(21) Appl. No.: 19/002,372

(22) Filed: Dec. 26, 2024

(30) Foreign Application Priority Data
Dec. 27, 2023 (JP) 2023-220770

(51) Int. Cl. C08L 53/00; C08F 12/08; C08F 220/14; G03F 7/00

(52) U.S. Cl. CPC C08L 53/00; C08F 12/08; C08F 220/14; G03F 7/0002

(57) ABSTRACT

A resin composition for forming a phase-separated structure, and a method for producing a structure having a phase-separated structure using the resin composition. The resin composition includes a block copolymer and a homopolymer, the block copolymer has a first block and a second block, the first block and the homopolymer each independently include a polymer having a repeating structure of a constituent unit represented by formula (b1), and at least one terminal of a main chain of the homopolymer has a structure I represented by formula (b2-I) or a structure II represented by formula (b2-II)

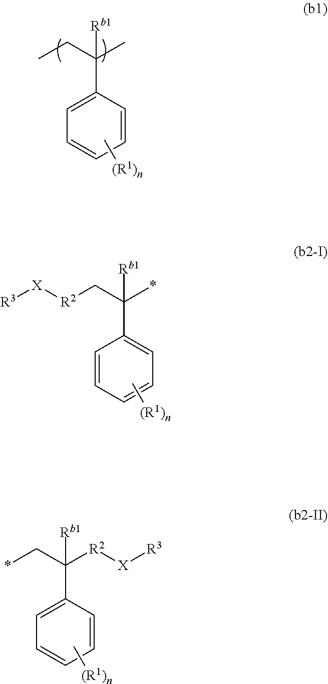

This application claims priority to Japanese Patent Application No. 2023-220770, filed Dec. 27, 2023, the entire content of which is incorporated herein by reference.

### BACKGROUND OF THE INVENTION

### Field of the Invention

The present invention relates to a resin composition for forming a phase-separated structure and a method for producing a structure having a phase-separated structure.

### Related Art

In recent years, following further miniaturization of a large-scale integrated circuit (LSI), a technique for processing a finer structure has been demanded. In response to this demand, a technique has been developed to form finer patterns by utilizing a phase-separated structure formed by directed self-assembly of block copolymers in which mutually incompatible blocks are bonded to each other (see Patent Document 1, for example).

The block copolymers separate (phase-separate) into micro-regions due to repulsion between the mutually incompatible blocks, and then are subjected to heat treatment, etc. to form a structure having a regular periodic structure. Specific examples of the periodic structure include a cylinder (columnar), lamella (plate-like) and sphere (spherical).

To use this phase-separated structure of block copolymers, it is essential that the self-assembled nanostructures formed by micro-phase separation be formed only in specific regions and be arranged in the desired direction. To control the position and orientation of these nanostructures, processes such as graphene epitaxy, which controls phase separation patterns by guiding patterns, and chemical epitaxy, which controls phase separation patterns by differences in the chemical state of the substrate, have been proposed (see, for example, Non-Patent Document 1).
Patent Document 1: Japanese Unexamined Patent Application, Publication No. 2008-36491
Non-Patent Document 1: Proc. SPIE 7637, Alternative Lithographic Technologies II, 76370G (1 Apr. 2010)

### SUMMARY OF THE INVENTION

In the method for forming a pattern by using the phase-separated structure, it is necessary to prepare a block copolymer having a period (L₀) of a structure corresponding to one pitch. Therefore, it is necessary to individually prepare block copolymers corresponding to a plurality of pitch designs. When one block copolymer can correspond to a plurality of the pitches, the process margin widely broadens.

To broaden the process margin, a resin composition for forming a phase-separated structure in which a homopolymer of polystyrene or polymethyl methacrylate is added to the block copolymer has been adopted, but a difference in the pitch before and after the addition hardly broadens.

The present invention has been made in view of the above circumstances, with the object of providing a resin composition for forming a phase-separated structure that can improve the process margin and a method for producing a structure having a phase-separated structure using this resin composition.

As a result of extensive studies by the present inventors to solve the above problem, the present invention has been completed based on findings that the above object can be solved by using a homopolymer having a predetermined structure at at least one terminal, in addition to the block copolymer. Specifically, the present invention provides the following aspects.

[1] A resin composition for forming a phase-separated structure, the resin composition including: a block copolymer; and a homopolymer, in which
the block copolymer has a first block and a second block,
the first block and the homopolymer are each independently constituted by a polymer having a repeating structure of a constituent unit represented by formula (b1), and
at least one terminal of a main chain of the homopolymer has a structure I represented by formula (b2-I) or a structure II represented by formula (b2-II):

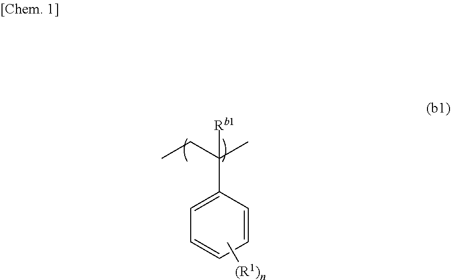

wherein, in the formula (b1), R^{b1} is a hydrogen atom or a methyl group, R¹ is an alkyl group optionally having an oxygen atom or a silicon atom, n is an integer between 0 and 5 inclusive, and when n is an integer of 2 or more, a plurality Of R¹ may be same as or different from each other,

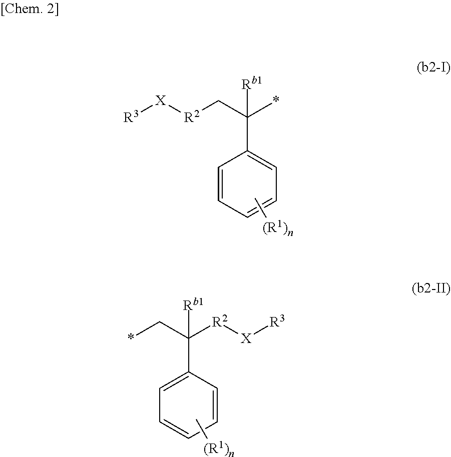

wherein, in the formula (b2-1) and the formula (b2-II), R^{b1}, R¹, and n are same as those in the formula (b1), R² is an alkylene group, X is a group represented by —O—, —C(═O)—, —O—C(═O)—, or —C(═O)—O—, R³ is a hydrogen atom or a monovalent organic group, the monovalent organic group as R³ is free of a protonic acid group and is free of two or more groups represented by —Y—H, Y is a group 16 element in a periodic table, a group represented by —X—R³ is not a carboxy group, and * is a bond.

[2] The resin composition for forming a phase-separated structure according to [1], in which the X is a group represented by —O—.

[3] The resin composition for forming a phase-separated structure according to [1] or [2], in which the R³ is a hydrogen atom, an alkyl group, or a cyclic ether group.

[4] The resin composition for forming a phase-separated structure according to any one of [1] to [3], in which an amount of the homopolymer is 1 part by mass or more and 50 parts by mass or less relative to 100 parts by mass of the block copolymer.

[5] The resin composition for forming a phase-separated structure according to any one of [1] to [4], in which the block copolymer has a number-average molecular weight of 20,000 or more and 200,000 or less.

[6] The resin composition for forming a phase-separated structure according to any one of [1] to [5], in which the homopolymer has a number-average molecular weight of 1,000 or more and 10,000 or less.

[7] The resin composition for forming a phase-separated structure according to any one of [1] to [6], in which a proportion of a number of moles of a constituent unit of the first block to a sum of the number of moles of the constituent unit of the first block and a number of moles of the constituent unit of the second block is 20 mol % or more and 80 mol % or less.

[8] A method for producing a structure having a phase-separated structure, the method comprising:
applying the resin composition for forming a phase-separated structure according to any one of [1] to [7] on a support to form a layer containing a block copolymer; and
phase separating the layer containing the block copolymer.

According to the present invention, a resin composition for forming a phase-separated structure that can improve the process margin and a method for producing a structure having a phase-separated structure using this resin composition can be provided.

### BRIEF DESCRIPTION OF THE DRAWINGS

FIG. 1 is a schematic process diagram illustrating an exemplary embodiment of a method for producing a structure having a phase-separated structure; and

FIG. 2 is a diagram illustrating an exemplary embodiment of an optional process.

### DETAILED DESCRIPTION OF THE INVENTION

Although embodiments of the present invention will be described below in detail, the present invention is not limited to the embodiments below in any way and can be implemented with modifications as appropriate within the scope of the object of the present invention.

As used herein, the term “aliphatic” is defined as a concept relative to aromatic and means a group, a compound, etc. having no aromaticity. Unless otherwise specified, the term “alkyl group” means a linear- or branched-chain monovalent saturated hydrocarbon group. The same applies to an alkyl group in an alkoxy group. Unless otherwise specified, the term “cycloalkyl group” means a monocyclic cyclic saturated hydrocarbon group. Unless otherwise specified, the term “alkylene group” means a linear- or branched-chain divalent saturated hydrocarbon group. The term “halogenated alkyl group” means a group in which a portion or all of hydrogen atoms in an alkyl group is substituted with a halogen atom. Examples of the halogen atom include a fluorine atom, a chlorine atom, a bromine atom, or an iodine atom. The term “fluorinated alkyl group” or “fluorinated alkylene group” means a group in which a portion or all of the hydrogen atoms in an alkyl group or an alkylene group is substituted with a fluorine atom. The term “constituent unit” means a monomer unit (monomeric unit) constituting a polymer compound (resin, polymer, or copolymer). The phrase “constituent unit derived from” means a constituent unit derived from the cleavage of an ethylenic double bond or a cyclic ether. The phrase “optionally having a substituent” includes both of a case where a hydrogen atom (—H) is substituted with a monovalent group and a case where a methylene group (—CH₂—) is substituted with a divalent group. The term “exposure” means general irradiation with radiation. Unless otherwise specified, the term “α-position (carbon atom at an α-position)” means a carbon atom to which a side chain of a block copolymer is bonded. The term “carbon atom at an α-position” of a methyl methacrylate unit means a carbon atom to which a carbonyl group in methacrylic acid is bonded. The term “carbon atom at an α-position” of a styrene unit means a carbon atom to which a benzene ring is bonded. Unless otherwise specified, the term “number-average molecular weight” (Mn) and “weight-average molecular weight” (Mw) mean a number-average molecular weight and a weight-average molecular weight in terms of standard polystyrene determined by gel permeation chromatography (GPC) measurement. When a value of Mn or Mw is followed by a unit (gmol⁻¹), the value represents a molar mass. Herein, an asymmetric carbon may exist depending on the structure represented by a chemical formula, and thus an enantiomer or a diastereomer may exist. In such cases, one formula is used for representing these isomers. These isomers may be used alone or used as a mixture.

As used herein, the term “structural period” means a period of a phase structure observed when a structure having a phase-separated structure is formed and refers to a sum of lengths of phases incompatible with each other. When a phase-separated structure forms a cylinder structure perpendicular to a surface of a substrate, the structural period (L₀) is the distance between centers (pitch) of the two adjacent cylinder structures.

It is known that the structural period (L₀) is determined by inherent polymerization properties such as the degree of polymerization N and the Flory-Huggins interaction parameter X. That is, the larger the product of x and N “x·N”, the greater the mutual repulsion between the different blocks in the block copolymer. Therefore, in the case of x·N>10.5 (hereinafter, referred to as “intensity separation limit”), repulsion between different kinds of blocks in the block copolymer is large, leading to a stronger tendency to induce phase separation. Accordingly, at the intensity separation limit, the structural period is approximately N^{2/3}·x^{1/6}, and the relationship expressed in the following formula (cy) is satisfied. That is, the structural period is proportional to the degree of polymerization N, which correlates with the molecular weight and the molecular weight ratio between different blocks.

L₀∝a·N^{2/3}·x^{1/6} (cy)

[In the formula, L₀ denotes a structural period; a is a parameter indicating a size of a monomer; N denotes a degree of polymerization; and x is an interaction parameter in which a higher value means higher phase separation performance.]

Accordingly, the structural period (L₀) can be controlled by adjusting the composition and total molecular weight of block copolymers.

Resin Composition for Forming Phase-Separated Structure A resin composition for forming a phase-separated structure comprises a block copolymer and a homopolymer. The block copolymer has a first block and a second block. The first block and the homopolymer are each independently constituted by a polymer having a repeating structure of a constituent unit represented by the following formula (b1). At least one terminal of a main chain of the homopolymer has a structure I represented by the following formula (b2-I) or a structure II represented by the following formula (b2-II).

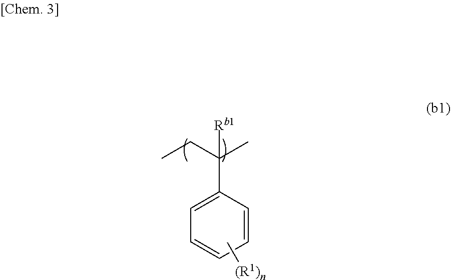

(In the formula (b1), R^{b1} is a hydrogen atom or a methyl group, R¹ is an alkyl group optionally having an oxygen atom or a silicon atom, n is an integer between 0 and 5 inclusive, and when n is an integer of 2 or more, a plurality of R¹ may be the same as or different from each other.)

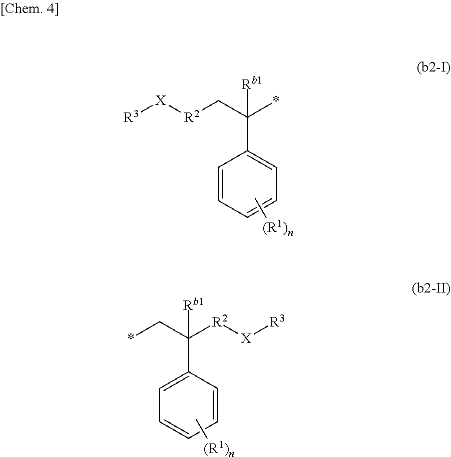

(In the formula (b2-I) and the formula (b2-II), R^{b1}, R¹, and n are the same as those in the formula (b1), R² is an alkylene group, X is a group represented by —O—, —C(═O)—, —O—C(═O)—, or —C(═O)—O—, R³ is a hydrogen atom or a monovalent organic group, the monovalent organic group as R³ is free of a protonic acid group and is free of two or more groups represented by —Y—H, Y is a group 16 element in a periodic table, a group represented by —X—R³ is not a carboxy group, and * is a bond.)

### <Block Copolymer>

The block copolymer has a first block and a second block.

### [First Block]

The first block is constituted by a polymer having a repeating structure of a constituent unit represented by the following formula (b1).

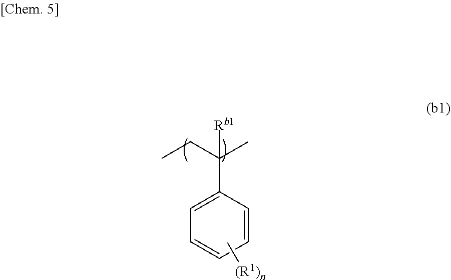

(In the formula (b1), R^{b1} is a hydrogen atom or a methyl group, R¹ is an alkyl group optionally having an oxygen atom or a silicon atom, n is an integer between 0 and 5 inclusive, and when n is an integer of 2 or more, a plurality of R¹ may be the same as or different from each other.)

The alkyl group optionally having an oxygen atom and/or a silicon atom in R¹ is preferably an alkyl group optionally interrupted by an oxygen atom and optionally substituted with an alkylsilyl group. Specific examples thereof include an alkyl group, an alkylsilyl group, an alkylsilylalkyl group, an alkylsilyloxy group, an alkylsilyloxyalkyl group, and an alkoxy group.

Examples of the alkyl group in R¹ include a methyl group, an ethyl group, a n-propyl group, an isopropyl group, a n-butyl group, a sec-butyl group, and a tert-butyl group.

The alkylsilyl group is preferably a trialkylsilyl group. Specific examples thereof include a trimethylsilyl group. The alkylsilylalkyl group is preferably a trialkylsilylalkyl group. Specific examples thereof include a trimethylsilylmethyl group, a 2-trimethylsilylethyl group, and a 3-trimethylsilyl-n-propyl group. The alkylsilyloxy group is preferably a trialkylsilyloxy group. Specific examples thereof include a trimethylsilyloxy group. The alkylsilyloxyalkyl group is preferably a trialkylsilyloxyalkyl group. Specific examples thereof include a trimethylsilyloxymethyl group, a 2-trimethylsilyloxyethyl group, and a 3-trimethylsilyloxy-n-propyl group. Examples of the alkoxy group include a methoxy group, an ethoxy group, a n-propoxy group, an isopropoxy group, a n-butoxy group, a sec-butoxy group, and a tert-butoxy group.

The number of carbon atoms of an entirety of the alkyl group in R¹ optionally interrupted by an oxygen atom and optionally substituted with the alkylsilyl group is preferably 1 or more and 10 or less, more preferably 1 or more and 5 or less, further preferably 1 or more and 3 or less, and particularly preferably 1 or 2.

n is preferably an integer between 0 and 3 inclusive, more preferably 0 or 1, and further preferably 0.

### [Second Block]

The second block is preferably constituted by a polymer having a repeating structure of a constituent unit derived from an (α-substituted) acrylic acid, a polymer having a repeating structure of a constituent unit derived from an (α-substituted) acrylate ester, or a polymer having a repeating structure of a constituent unit of a siloxane or a derivative thereof, and more preferably constituted by a polymer having a repeating structure of a constituent unit derived from an (α-substituted) acrylate ester.

[Constituent Unit Derived from (α-Substituted) Acrylate Ester]

As used herein, “(α-substituted) acrylate ester” includes an acrylate ester and an acrylic acid derivative having a hydrogen atom bonded to a carbon atom at an α-position of an acrylate ester substituted with a substituent. Examples of the substituent in the (α-substituted) acrylate ester include an alkyl group having 1 or more and 5 or less carbon atoms, and a halogenated alkyl group having 1 or more and 5 or less carbon atoms. Among these, the alkyl group having 1 or more and 5 or less carbon atoms is preferable, and a methyl group is more preferable.

The (α-substituted) acrylate ester is preferably an (α-substituted) alkyl acrylate ester. The number of carbon atoms of the alkyl group in the (α-substituted) alkyl acrylate ester is preferably 1 or more and 10 or less, and more preferably 1 or more and 5 or less. Specific examples of the (α-substituted) acrylate ester include: acrylate esters such as methyl acrylate, ethyl acrylate, propyl acrylate, n-butyl acrylate, tert-butyl acrylate, cyclohexyl acrylate, octyl acrylate, nonyl acrylate, hydroxyethyl acrylate, hydroxypropyl acrylate, benzyl acrylate, anthracene acrylate, glycidyl acrylate, 3,4-epoxycyclohexylmethane acrylate, and propyl trimethoxysilane acrylate; and methacrylate esters such as methyl methacrylate, ethyl methacrylate, propyl methacrylate, n-butyl methacrylate, tert-butyl methacrylate, cyclohexyl methacrylate, octyl methacrylate, nonyl methacrylate, hydroxyethyl methacrylate, hydroxypropyl methacrylate, benzyl methacrylate, anthracene methacrylate, glycidyl methacrylate, 3,4-epoxycyclohexylmethane methacrylate, and propyl trimethoxysilane methacrylate.

Among the above, the (α-substituted) acrylate ester is preferably the alkyl acrylate ester or the alkyl methacrylate ester, more preferably methyl acrylate, ethyl acrylate, tert-butyl acrylate, methyl methacrylate, ethyl methacrylate, and t-butyl methacrylate, and further preferably methyl methacrylate.

The constituent unit derived from the (α-substituted) acrylate ester is preferably a constituent unit represented by the following formula (b3).

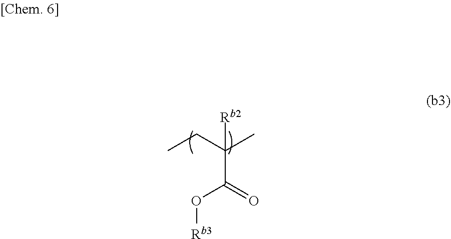

(In the formula, R^{b3} is an alkyl group having 1 or more and 10 or less carbon atoms, R^{b2} each independently is a hydrogen atom, an alkyl group having 1 or more and 5 or less carbon atoms, or a halogenated alkyl group having 1 or more and 5 or less carbon atoms, and a plurality of R^{b2} may be the same or different.)

The number of carbon atoms of the alkyl group in R^{b3} is preferably 1 or more and 5 or less, and more preferably 1 or more and 3 or less. The alkyl group in R^{b3} is preferably linear. Examples of the alkyl group in R^{b3} include a methyl group, an ethyl group, a n-propyl group, an isopropyl group, a n-butyl group, an isobutyl group, a sec-butyl group, a tert-butyl group, and a n-pentyl group. Among these, a methyl group, an ethyl group, and a n-propyl group are preferable, and a methyl group is more preferable.

Examples of the alkyl group having 1 or more and 5 or less carbon atoms in R^{b2} include a methyl group, an ethyl group, a propyl group, an isopropyl group, a n-butyl group, a sec-butyl group, a tert-butyl group, a n-pentyl group, a neopentyl group, an isopentyl group, a sec-pentyl group, a 3-pentyl group, and a tert-pentyl group. The halogenated alkyl group having 1 or more and 5 or less carbon atoms is a group in which a portion or all of hydrogen atoms in the alkyl group having 1 or more and 5 or less carbon atoms are substituted with a halogen atom. The halogen atom is particularly preferably a fluorine atom.

R^{b2} is preferably a hydrogen atom or an alkyl group having 1 or more and 5 or less carbon atoms, and in terms of industrial availability, more preferably a hydrogen atom or a methyl group, and further preferably a methyl group.

[Constituent Unit Derived from (α-Substituted) Acrylic Acid]

As used herein, “(α-substituted) acrylic acid” includes acrylic acid and an acrylic acid derivative having a hydrogen atom bonded to a carbon atom at an α-position of the acrylic acid substituted with a substituent.

Specific examples of the (α-substituted) acrylic acid include acrylic acid and methacrylic acid.

### [Constituent Unit of Siloxane or Derivative Thereof]

Specific examples of a siloxane or a derivative thereof include dimethylpolysiloxane, diethylpolysiloxane, diphenylpolysiloxane, and methylphenylpolysiloxane.

In the block copolymer, a proportion of the number of moles of a constituent unit of the first block to a sum of the number of moles of the constituent unit of the first block and the number of moles of the constituent unit of the second block is preferably 20 mol % or more and 80 mol % or less. The proportion of the number of moles of the constituent unit of the first block is more preferably 30 mol % or more, further preferably 45 mol % or more, and particularly preferably 55 mol % or more. The proportion of the number of moles of the constituent unit of the first block is more preferably 75 mol % or less, and further preferably 70 mol % or less.

The block copolymer may have another block in addition to the first block and the second block. In a preferable aspect, the block copolymer is a diblock copolymer constituted by the first block and the second block.

A number-average molecular weight (Mn) of the block copolymer is not particularly limited, and is preferably 10,000 or more and 300,000 or less, more preferably 15,000 or more and 250,000 or less, and further preferably 20,000 or more and 200,000 or less. A degree of dispersion of molecular weight (Mw/Mn) of each block constituting the block copolymer is preferably 1.0 or more and 1.5 or less, more preferably 1.0 or more and 1.4 or less, and further preferably 1.0 or more and 1.3 or less.

### <Homopolymer>

The homopolymer is constituted by a polymer having a repeating structure of a constituent unit represented by the following formula (b1). At least one terminal of a main chain of the homopolymer has a structure I represented by the following formula (b2-I) or a structure II represented by the following formula (b2-II).

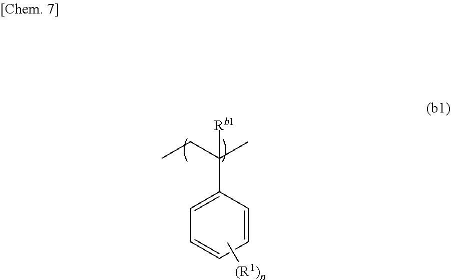

(In the formula (b1), R^{b1} is a hydrogen atom or a methyl group, R¹ is an alkyl group optionally having an oxygen atom or a silicon atom, n is an integer between 0 and 5 inclusive, and when n is an integer of 2 or more, a plurality of R¹ may be the same as or different from each other.)

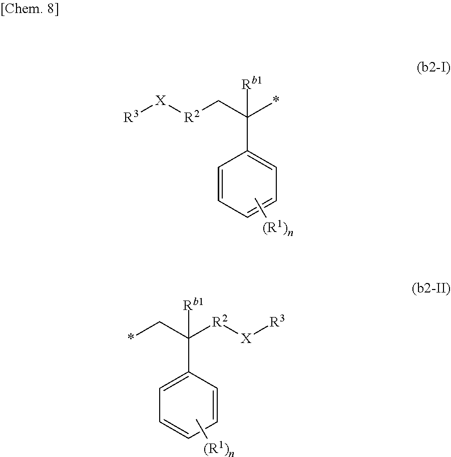

(In the formula (b2-I) and the formula (b2-II), R^{b1}, R¹, and n are the same as those in the formula (b1), R² is an alkylene group, X is a group represented by —O—, —C(═O)—, —O—C(═O)—, or —C(═O)—O—, R³ is a hydrogen atom or a monovalent organic group, the monovalent organic group as R³ is free of a protonic acid group and is free of two or more groups represented by —Y—H, Y is a group 16 element in a periodic table, a group represented by —X—R³ is not a carboxy group, and * is a bond.)

In the homopolymer, a preferable aspect of R^{b1}, R¹, and n in the formula (b1) are the same as R^{b1}, R¹, and n in the formula (b1) of the first block.

At least one terminal of the main chain of the homopolymer preferably has the structure II represented by formula (b2-II).

The number of carbon atoms of the alkylene group in R² is preferably 1 or more and 10 or less, more preferably 1 or more and 5 or less, and further preferably 1 or more and 3 or less. The alkylene group in R² is preferably linear. Examples of the alkylene group in R² include a methylene group, an ethane-1,2-diyl group, a propane-1,2-diyl group, a propane-1,3-diyl group, a butane-1,4-diyl group, and a pentane-1,5-diyl group. Among these, a methylene group, an ethane-1,2-diyl group, and a propane-1,3-diyl group are preferable, and an ethane-1,2-diyl group is more preferable.

X is preferably a group represented by —O—.

The number of carbon atoms of the monovalent organic group in R³ is preferably 1 or more and 30 or less, more preferably 1 or more and 20 or less, further preferably 1 or more and 10 or less, and particularly preferably 1 or more and 6 or less. Examples of the monovalent organic group in R³ include a chain hydrocarbon group, an alicyclic hydrocarbon group, an aromatic hydrocarbon group, and a heterocyclic group. Among these, a chain hydrocarbon group and a heterocyclic group are preferable.

The chain hydrocarbon group is preferably an alkyl group. Examples of the alkyl group include a methyl group, an ethyl group, a n-propyl group, an isopropyl group, a n-butyl group, an isobutyl group, a sec-butyl group, a tert-butyl group, and a n-pentyl group. Among these, a methyl group, an ethyl group, and a n-propyl group are preferable, and a methyl group is more preferable. Examples of the alicyclic hydrocarbon group include a cyclopropyl group, a cyclobutyl group, a cyclopentyl group, a cyclohexyl group, a norbornyl group, and an adamantyl group. Examples of the aromatic hydrocarbon group include a phenyl group, a naphthalenyl group, and an anthracenyl group. Examples of a hetero element in the heterocyclic group include an oxygen atom, a nitrogen atom, and a sulfur atom. The heterocyclic group is preferably an oxygen-containing heterocyclic group, and more preferably a cyclic ether group.

R³ is preferably a hydrogen atom, the chain hydrocarbon group, or the heterocyclic group, and more preferably a hydrogen atom, the alkyl group, or the cyclic ether group.

A number-average molecular weight (Mn) of the homopolymer is not particularly limited, and is preferably 500 or more and 50,000 or less, more preferably 800 or more and 20,000 or less, and further preferably 1,000 or more and 10,000 or less. A degree of dispersion of molecular weight (Mw/Mn) of the homopolymer is preferably 1.0 or more and 1.5 or less, more preferably 1.0 or more and 1.4 or less, and further preferably 1.0 or more and 1.3 or less.

An amount of the homopolymer is preferably 1 part by mass or more and 50 parts by mass or less, more preferably 3 parts by mass or more and 40 parts by mass or less, and further preferably 5 parts by mass or more and 35 parts by mass or less relative to 100 parts by mass of the block copolymer.

### [Method for Producing Homopolymer]

The homopolymer can be synthesized by living-anion polymerization etc. For example, for synthesizing polystyrene, an initiator is used for polymerizing styrene in an appropriate solvent, and then the polymerization is treated with a terminating agent. Use of an initiator having a group represented by —R²—X—R³ can introduce the above structure I at the initiation terminal of polystyrene, and use of a terminating agent having a group represented by —R²—X—R³ can introduce the above structure II at the termination terminal of polystyrene.

### <Organic Solvent Component>

The resin composition for forming a phase-separated structure preferably contains an organic solvent. The organic solvent component may be any organic solvent that can dissolve each of the used components to form a uniform solution. A given organic solvent selected from organic solvents conventionally known as a solvent of a composition containing a resin as a main component may be used.

Examples of the organic solvent component include lactones such as γ-butyrolactone; ketones such as acetone, methyl ethyl ketone, cyclohexanone, methyl-n-pentyl ketone, methyl isopentyl ketone, and 2-heptanone; polyhydric alcohols such as ethylene glycol, diethylene glycol, propylene glycol, and dipropylene glycol; polyhydric alcohol monoacetates such as ethylene glycol monoacetate, diethylene glycol monoacetate, propylene glycol monoacetate, or dipropylene glycol monoacetate; derivatives of the polyhydric alcohol such as a compound having an ether bond such as a monoalkyl ether or a monophenyl ether such as a monomethyl ether, a monoethyl ether, a monopropyl ether, a monobutyl ether, etc. of the polyhydric alcohols or the polyhydric alcohol monoacetates [among these, propylene glycol monomethyl ether acetate (PGMEA) or propylene glycol monomethyl ether (PGME) is preferable]; cyclic ethers such as dioxane; esters other than the polyhydric alcohol monoacetates and the derivative of the polyhydric alcohols described above, such as methyl lactate, ethyl lactate (EL), methyl acetate, ethyl acetate, butyl acetate, methyl pyruvate, ethyl pyruvate, methyl methoxypropionate, and ethyl ethoxypropionate; aromatic organic solvents such as anisole, ethyl benzyl ether, cresyl methyl ether, diphenyl ether, dibenzyl ether, phenetole, butyl phenyl ether, ethylbenzene, diethylbenzene, pentylbenzene, isopropylbenzene, toluene, xylene, cymene, and mesitylene. The organic solvent component may be used alone, or two or more may be used as a mixed solvent. Among these, propylene glycol monomethyl ether acetate (PGMEA), propylene glycol monomethyl ether (PGME), cyclohexanone, and ethyl lactate (EL) are preferable.

The organic solvent component contained in the resin composition for forming a phase-separated structure is not particularly limited. The organic solvent component is appropriately set according to the coating film thickness such that the resin composition for forming a phase-separated structure has a concentration with which the composition can be applied. The organic solvent component is typically used such that the solid-content concentration of the resin composition for forming a phase-separated structure is in a range of between 0.2 mass % or more and 70 mass % or less, preferably between 0.2 mass % or more and 50 mass % or less.

### <Optional Component>

The resin composition for forming a phase-separated structure may contain optional components other than the aforementioned block copolymer, homopolymer, and organic solvent component. Examples of the optional component include another resin, a surfactant, a dissolution inhibiting agent, a plasticizing agent, a stabilizing agent, a coloring agent, an anti-halation agent, a dye, a sensitizing agent, a base proliferating agent, and a basic compound.

### <<Method for Producing Structure Having Phase-Separated Structure>>

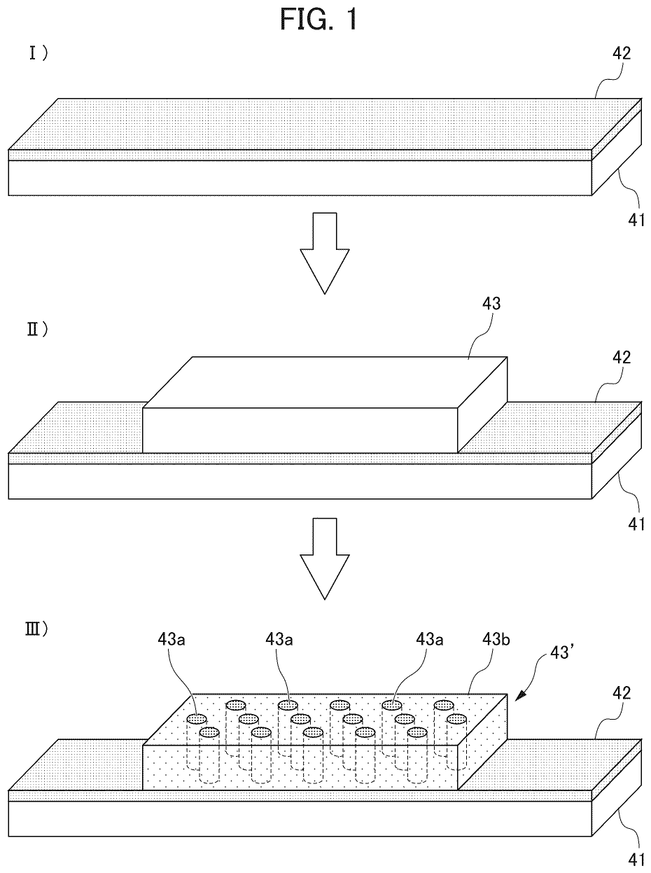

A method for producing a structure having a phase-separated structure includes: applying the resin composition for forming a phase-separated structure on a support to form a layer containing a block copolymer (hereinafter, referred to as “step (i)”); and phase separating the layer containing the block copolymer (hereinafter, referred to as “step (ii)”). Hereinafter, this method for producing a structure having a phase-separated structure will be specifically described with reference to FIG. 1. Note that the method for producing a structure having a phase-separated structure is not limited to the aspect specifically illustrated in FIG. 1.

FIG. 1 illustrates an exemplary embodiment of the method for producing a structure having a phase-separated structure. In the embodiment illustrated in FIG. 1, an undercoat agent is firstly applied on a support 41 to form an undercoat agent layer 42 (FIG. 1(I)). Next, the resin composition for forming a phase-separated structure is applied on the undercoat agent layer 42 to form a layer (BCP layer) 43 containing the block copolymer (FIG. 1 (II); the above is the step (i)). Next, the BCP layer is annealed by heating to separate the BCP layer 43 into a phase 43a and a phase 43b (FIG. 1 (III); the step (ii)). According to this producing method of the embodiment, namely the producing method including the step (i) and the step (ii), a structure 43′ having a phase-separated structure is produced on the support 41 on which the undercoat agent layer 42 is formed.

<Step (i)>

In the step (i), the resin composition for forming a phase-separated structure is applied on the support 41 to form the BCP layer 43. In the embodiment illustrated in FIG. 1, the undercoat agent is firstly applied on the support 41 to form the undercoat agent layer 42. Providing the undercoat agent layer 42 on the support 41 can achieve hydrophilic-hydrophobic balance between the support 41 surface and the layer (BCP layer) 43 containing the block copolymer. That is, the undercoat agent layer 42 containing the resin component having the constituent unit constituting the first block increases adhesiveness between the phase composed of the first block in the BCP layer 43 and the support 41. The undercoat agent layer 42 containing the resin component having the constituent unit constituting the second block increases adhesiveness between the phase composed of the second block in the BCP layer 43 and the support 41. According to this, the phase separation of the BCP layer 43 easily forms the phase-separated structure oriented in the direction perpendicular to the support 41 surface.

### Undercoat Agent:

As the undercoat agent, a resin composition may be used. The resin composition for the undercoat agent may be appropriately selected from among conventionally known resin compositions used for forming a thin film according to the type of the blocks constituting the block copolymer. The resin composition for the undercoat agent may be, for example, a thermally polymerizable resin composition or may be a photosensitive resin composition such as a positive-type resist composition or a negative-type resist composition. Furthermore, a non-polymerizable film formed by applying a compound serving as a surface-treating agent may also be used as the undercoat agent layer. For example, a siloxane-based organic monomolecular film formed by applying phenethyltrichlorosilane, octadecyltrichlorosilane, hexamethyldisilazane, etc., as the surface-treating agent can also be suitably used as the undercoat agent layer.

Examples of the resin composition as above include: a resin composition containing a resin having both the constituent units respectively constituting the first block and the second block; and a resin composition containing a resin having both constituent units having high compatibility with the blocks constituting the block copolymer. As the resin composition for the undercoat agent, preferably used are: a composition containing a resin having both styrene and methyl methacrylate as constituent units; and a compound or composition having a moiety having high compatibility with styrene, such as an aromatic ring, and a moiety having high compatibility with methyl methacrylate (such as a highly polar functional group). Examples of the resin having both styrene and methyl methacrylate as constituent units include a random copolymer of styrene and methyl methacrylate, and an alternate polymer of styrene and methyl methacrylate (polymer in which each polymer is alternately copolymerized). Examples of the composition having both of a moiety having high compatibility with styrene and a moiety having high compatibility with methyl methacrylate include a composition containing a resin obtained by polymerizing at least a monomer having an aromatic ring and a monomer having a highly polar functional group. Examples of the monomer having an aromatic ring include a monomer having an aryl group in which one hydrogen atom is removed from an aromatic hydrocarbon ring, such as a phenyl group, a biphenyl group, a fluorenyl group, a naphthyl group, an anthryl group, or a phenanthryl group, or a heteroaryl group in which a portion of carbon atoms constituting a ring on the aforementioned groups is substituted with a heteroatom such as an oxygen atom, a sulfur atom, or a nitrogen atom. Furthermore, examples of the monomer having a highly polar functional group include: a monomer having a trimethoxysilyl group, a trichlorosilyl group, an epoxy group, a glycidyl group, a carboxy group, a hydroxy group, a cyano group, or a hydroxyalkyl group in which a portion of hydrogen atoms in an alkyl group is substituted with a hydroxy group. Other examples of the compound having both a moiety having high compatibility with styrene and a moiety having high compatibility with methyl methacrylate include: a compound having both an aryl group and a highly polar functional group, such as phenethyltrichlorosilane; and a compound having both an alkyl group and a highly polar functional group, such as an alkylsilane compound.

The resin composition for the undercoat agent can be produced by dissolving the aforementioned resin in a solvent. Such a solvent may be any solvent that can dissolve each component to be used and form a homogeneous solution. Examples thereof include the same solvents as the organic solvent components exemplified in the description for the resin composition for forming a phase-separated structure.

The type of the support 41 is not particularly limited as long as the resin composition can be applied on the surface. Examples thereof include: a substrate composed of an inorganic material such as silicon, a metal (such as copper, chromium, iron, and aluminum), glass, titanium oxide, silica, and mica; a substrate composed of an oxide such as SiO₂; a substrate composed of a nitride such as SiN; a substrate composed of an oxynitride such as SiON; and a substrate composed of an organic material such as acryl resin, polystyrene, cellulose, cellulose acetate, or a phenolic resin. Among these, a silicon substrate (Si substrate) or a metal substrate is suitable, a Si substrate or a copper substrate (Cu substrate) is more suitable, and a Si substrate is particularly suitable. The size and shape of the support 41 are not particularly limited. The support 41 does not necessarily have a smooth surface, and substrates having various shapes can be appropriately selected. Examples thereof include a substrate having a curved surface, a flat plate having an uneven surface, or a flaky substrate may be used.

An inorganic and/or organic film may be provided on the surface of the support 41. An example of the inorganic film is an inorganic antireflection film (inorganic BARC). An example of the organic film is an organic antireflection film (organic BARC). The inorganic film can be formed by, for example, applying an inorganic antireflection film composition such as a silicon-based material on the support, and baking the resultant. The organic film can be formed by, for example, applying a material for forming an organic film in which a resin component etc. to constitute the film is dissolved in an organic solvent on the substrate with a spinner etc., and performing a baking treatment under a heating condition of preferably 200° C. or higher and 300° C. or lower for preferably 30 seconds or more and 300 seconds or less, and more preferably for 60 seconds or more and 180 seconds or less. This material for forming an organic film does not necessarily require sensitivity to light or electron beam, such as a resist film, and may or may not have such sensitivity. Specifically, a resist or a resin commonly used for producing semiconductor elements or liquid crystal display elements may be used. Furthermore, the material for forming an organic film is preferably a material capable of forming an organic film that can be subjected to etching, particularly dry-etching, so that a pattern formed by processing the BCP layer 43 and composed of the block copolymer can be transferred to the organic film by etching the organic film using the pattern to form the organic film pattern. Among these, a material capable of forming an organic film that can be subjected to etching such as oxygen plasma etching is preferable. Such a material for forming an organic film may be a material conventionally used for forming an organic film such as organic BARC. Examples thereof include: the ARC series, manufactured by Nissan Chemical Corporation; the AR series, manufactured by Rohm and Haas Japan Ltd.; and the SWK series, manufactured by TOKYO OHKA KOGYO CO., LTD.

A method for forming the undercoat agent layer 42 by applying the undercoat agent on the support 41 is not particularly limited, and conventionally known methods may be used to form the undercoat agent layer 42. For example, the undercoat agent is applied on the support 41 by a conventionally known method such as spin coating or by using a spinner to form a coating film, which is then dried to form the undercoat agent layer 42. A method for drying the coating film may be any as long as a solvent included in the undercoat agent can be volatilized, and an example thereof includes a method of baking. In this case, the baking temperature is preferably 80° C. or higher and 300° C. or lower, more preferably 180° C. or higher and 270° C. or lower, and further preferably 220° C. or higher and 250° C. or lower. The baking time is preferably 30 seconds or more and 600 seconds or less, and more preferably 60 seconds or more and 600 seconds or less. A thickness of the undercoat agent layer 42 after drying the coating film is preferably about 10 nm or more and 100 nm or less, and more preferably about 40 nm or more and 90 nm or less.

The surface of the support 41 may be cleaned in advance before forming the undercoat agent layer 42 on the support 41. Cleaning the surface of the support 41 improves coatability of the undercoat agent. A conventionally known cleaning treatment method may be used, and examples thereof include an oxygen plasma treatment, an ozone oxidation treatment, an acid alkali treatment, and a chemical modification treatment.

After the undercoat agent layer 42 is formed, the undercoat agent layer 42 may be rinsed by using a rinsing liquid such as a solvent, as necessary. Since the rinsing removes uncrosslinked portions etc. in the undercoat agent layer 42, compatibility with at least one block constituting the block copolymer is improved, and thus, the phase-separated structure oriented in the direction perpendicular to the surface of the support 41 and composed of a cylinder structure is to be easily formed. The rinsing solution may be any liquid that can dissolve the uncrosslinked portions. Solvents such as propylene glycol monomethyl ether acetate (PGMEA), propylene glycol monomethyl ether (PGME), and ethyl lactate (EL), or commercially available thinner solutions can be used. After the cleaning, post-baking may be performed to volatilize the rinsing solution. A temperature condition during this post-baking is preferably 80° C. or higher and 300° C. or lower, and more preferably 100° C. or higher and 270° C. or lower. The baking time is preferably 30 seconds or more and 500 seconds or less, and more preferably 60 seconds or more and 240 seconds or less. The thickness of the undercoat agent layer 42 after this post-baking is preferably about 1 nm or more and 10 nm or less, and more preferably about 2 nm or more and 7 nm or less.

Next, the layer (BCP layer) 43 containing the block copolymer is formed on the undercoat agent layer 42. A method for forming the BCP layer 43 on the undercoat agent layer 42 is not particularly limited, and examples thereof include a method in which the resin composition for forming a phase-separated structure of the aforementioned embodiment is applied on the undercoat agent layer 42 by a conventionally known method such as spin coating or by using a spinner to form a coating film, and then drying the coating film.

A thickness of the BCP layer 43 may be any as long as the thickness is sufficient for inducing the phase separation, and is preferably 20 nm or more and 100 nm or less, and more preferably 20 nm or more and 80 nm or less with consideration of the type of the support 41 or the structural period size, uniformity of the nano-structure, etc. of the phase separated structure to be formed. For example, when the support 41 is a Si substrate, the thickness of the BCP layer 43 is regulated to be preferably 10 nm or more and 100 nm or less, and more preferably 20 nm or more and 80 nm or less.

<Step (ii)>

In the step (ii), the BCP layer 43 formed on the support 41 is phase-separated. The support 41 after the step (i) is subjected to an annealing treatment by heating and the block copolymer is selectively removed to form a phase-separated structure such that at least a portion of the support 41 surface is exposed. That is, a structure having a phase-separated structure 43′ that is phase-separated into the phase 43a and the phase 43b is produced on the support 41. The temperature condition during the annealing treatment is preferably a temperature higher than or equal to the glass transition temperature of the used block copolymer and lower than the pyrolysis temperature of the used block copolymer. For example, when the block copolymer is a polystyrene-polymethyl methacrylate (PS-PMMA) block copolymer (weight average molecular weight: 5000 or more and 100000 or less), the temperature condition is preferably 180° C. or higher and 270° C. or lower. The heating time is preferably 30 seconds or more and 3600 seconds or less. The annealing treatment is preferably performed in a less reactive gas such as nitrogen.

### <Optional Step>

The method for producing a structure having a phase-separated structure is not limited to the aforementioned embodiment, and may include a step (optional step) other than the steps (i) and (ii).

Examples of the optional step include a step of selectively removing a phase composed of at least one block of the first block and the second block constituting the block copolymer in the BCP layer 43 (hereinafter referred to as “step (iii)”), and a guide pattern formation step.

—Step (iii)

In the step (iii), a phase composed of at least one block of the first block and the second block constituting the block copolymer is selectively removed from the BCP layer, which is formed on the undercoat agent layer 42. This results in formation of a fine pattern (polymer nanostructure).

Examples of the method for selectively removing the phase composed of the block include: a method for subjecting the BCP layer to an oxygen plasma treatment; and a method for subjecting the BCP layer to a hydrogen plasma treatment. For example, the BCP layer containing the block copolymer is phase-separated, and then the BCP layer is subjected to the oxygen plasma treatment, the hydrogen plasma treatment, etc. to selectively not remove the phase composed of the first block and to selectively remove the phase composed of the second block.

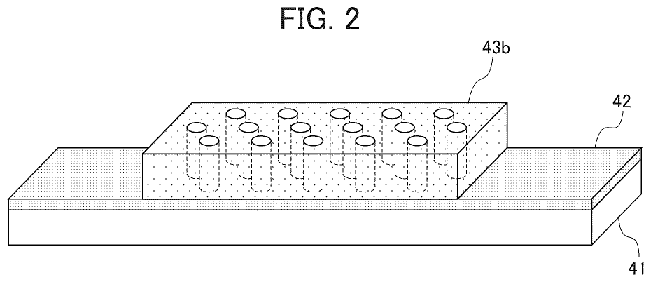

FIG. 2 illustrates an exemplary embodiment of the step (iii). In the embodiment illustrated in FIG. 2, the phase 43a is selectively removed by subjecting the structure 43′ produced on the support 41 in the step (ii) to the oxygen plasma treatment to selectively remove the phase 43a and to form a separated pattern (polymer nanostructure) composed of separated phases 43b. In this case, the phase 43b is the phase composed of the first block, and phase 43a is the phase consisting of the second block.

The support 41 with the pattern formed by the phase separation of the BCP layer 43 composed of the block copolymer as described above can be used as is, or the shape of the pattern (polymer nanostructure) on the support 41 can be changed by further heating. The temperature condition during the heating is preferably a temperature higher than or equal to a glass transition temperature of the used block copolymer and lower than the pyrolysis temperature of the used block copolymer. The heating is preferably performed in a less reactive gas such as nitrogen.

### —Guide Pattern Formation Step

The method for producing a structure having a phase-separated structure may also include a step of providing a guide pattern on the undercoat agent layer (guide pattern formation step) between the aforementioned step (i) and step (ii). This can control the array structure of the phase-separated structure. For example, even for block copolymers that form a random fingerprint-like phase-separated structure without guide pattern, a groove structure of a resist film can be provided on the surface of the undercoat agent layer to obtain a phase-separated structure oriented along the groove. According to the principle as above, the guide pattern may be provided on the undercoat agent layer 42. The compatibility of the surface of the guide pattern to any of the blocks constituting the above block copolymer facilitates the formation of a phase-separated structure composed of a cylinder structure and oriented in the direction perpendicular to the support surface.

The guide pattern can be formed by, for example, using a resist composition. For the resist composition forming the guide pattern, a resist composition having compatibility with any of the blocks constituting the above block copolymers can be appropriately selected for use from among resist compositions commonly used for forming resist patterns or their modifications. The resist composition may be either of: a positive-type resist composition to form a positive-type pattern, namely an exposed area of a resist film is dissolved and removed; or a negative-type resist composition to form a negative-type pattern, namely an unexposed area of a resist film is dissolved and removed, but a negative-type resist composition is preferable. The negative-type resist composition is preferably a resist composition containing, for example, an acid generator and a base material component having a solubility in an organic solvent-containing developing solution that decreases under action of an acid, the base material component containing a resin component having a constituent unit degraded under action of an acid to have increased polarity. After the BCP composition is poured onto the undercoat agent layer with the formed guide pattern, an annealing treatment is performed to induce the phase separation. Thus, a composition capable of forming a resist film while having excellent solvent resistance and heat resistance is preferable as the resist composition for forming the guide pattern.

### EXAMPLES

The present invention will now be described in more detail based on Examples, but the invention is not limited to these examples.

The block copolymer (BCP) used in Examples was a block copolymer consisting of a block (PS) composed of polystyrene and a block (PMMA) composed of polymethyl methacrylate. Table 1 and Table 2 show a number-average molecular weight (Mn), and a proportion of the number of moles of the PS constituent unit to a sum of the number of moles of constituent units of each of BCP.

Hereinafter, the homopolymers used in Example will be described.

### <Synthesis of Homopolymer 1 (HP 1)>

Under an argon atmosphere, 323 mg (7.61 mmol) of lithium chloride (LiCl) and 150 g of tetrahydrofuran (THF) were added to a Schlenk flask, and the mixture was cooled to −78° C. Under an argon atmosphere after the inside of the flask was dehydrated and degassed, 7.5 mL of sec-BuLi (hexane/cyclohexane mixed solution at 2.65 mol/L, 8.47 mmol) was added as an anionic polymerization initiator. Subsequently, 16.5 ml of styrene (143.54 mmol) was fed, and the mixture was stirred at −78° C. for 30 minutes. After the stirring, 0.62 ml (47.85 mmol) of a compound A-1 was fed, the mixture was stirred at −40° C. for 120 minutes, and then a temperature of the reaction liquid was raised to room temperature. The obtained reaction polymerization liquid was added dropwise to a large amount of methanol to precipitate a polymer, resulting in sedimentation of a white powder. The sedimented white powder was washed with a large amount of methanol, then washed with a large amount of pure water, and dried to obtain 13.22 g of a precursor 1 (yield: 89.0%). The precursor 1 had a number-average molecular weight (Mn) in terms of standard polystyrene determined by GPC measurement was 2,100, and a degree of dispersion of molecular weight (Mw/Mn) was 1.07.

Into a three-neck flask to which a thermometer, a reflux tube, and a nitrogen-introducing tube were connected, 4.52 g of the precursor 1 and THE (adjusted to be the precursor 1 at 10 mass %) were added, and 450 mg (10 parts by mass relative to 100 parts by mass of the precursor 1) of p-toluenesulfonic acid monohydrate (p-TSA) was fed, and the mixture was stirred for 20 minutes and then stirred at 40° C. for 6 hours. The reaction liquid was returned to room temperature, and the obtained reaction liquid was added dropwise to a large amount of methanol (or hexane etc.) to precipitate a polymer, resulting in sedimentation of a white powder. The sedimented white powder was washed with a large amount of methanol (or hexane etc.), then washed with a large amount of pure water, and dried to obtain 4.29 g of a homopolymer 1 (HP 1) (yield: 95.0%). The number-average molecular weight (Mn) in terms of standard polystyrene determined by GPC measurement was 2,000, and the degree of dispersion of molecular weight (Mw/Mn) was 1.07. In the following reaction formula, n1 is the number of repetition of the styrene unit.

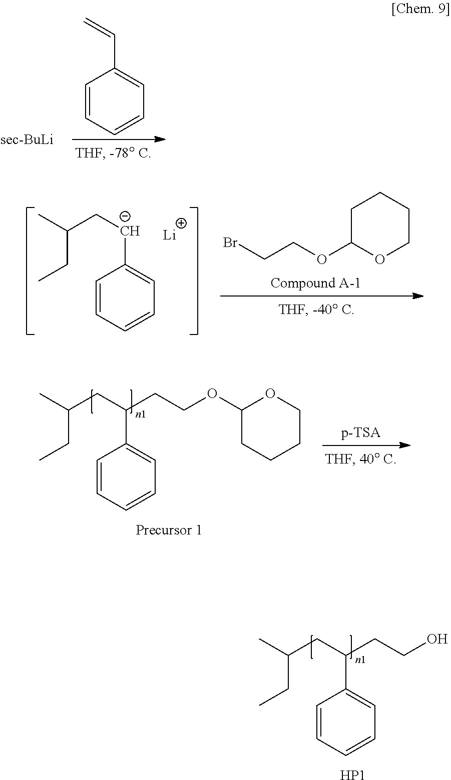

Similarly obtained were: HP 1 having a number-average molecular weight (Mn) of 3,000 and a degree of dispersion of molecular weight (Mw/Mn) of 1.07; HP 1 having a number-average molecular weight (Mn) of 4,000 and a degree of dispersion of molecular weight (Mw/Mn) of 1.07; and HP 1 having a number-average molecular weight (Mn) of 5,000 and a degree of dispersion of molecular weight (Mw/Mn) of 1.07.

### <Synthesis of Homopolymer 2 (HP 2)>

The precursor 1 obtained by the same method as the synthesis of HP 1 was used as a homopolymer 2 (HP 2). The number-average molecular weight (Mn) in terms of standard polystyrene determined by GPC measurement was 2,000, and the degree of dispersion of molecular weight (Mw/Mn) was 1.07.

### <Synthesis of Homopolymer 3 (HP 3)>

In the synthesis of HP 1, a compound A-2 (2-bromoethyl methyl ether) was fed instead of feeding the compound A-1, the mixture was stirred at −40° C. for 120 minutes, and then a temperature of the reaction liquid was raised to room temperature. The obtained reaction polymerization liquid was added dropwise to a large amount of methanol to precipitate a polymer, resulting in sedimentation of a white powder. The sedimented white powder was washed with a large amount of methanol, then washed with a large amount of pure water, and dried to obtain a homopolymer 3 (HP 3). The number-average molecular weight (Mn) in terms of standard polystyrene determined by GPC measurement was 2,000, and the degree of dispersion of molecular weight (Mw/Mn) was 1.09. In the following reaction formula, n1 is the number of repetition of the styrene unit.

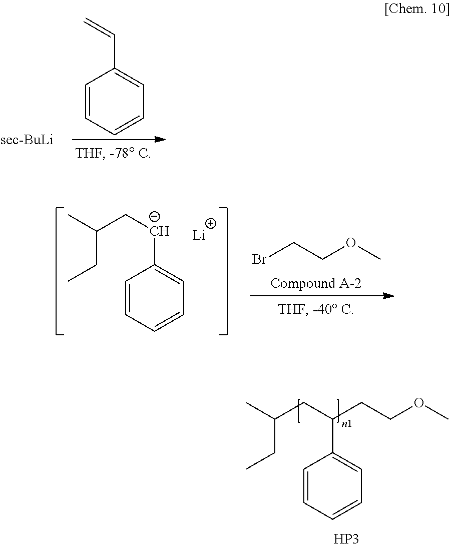

### <Synthesis of Homopolymer 4 (HP 4)>

A homopolymer 4 (HP 4) was obtained by the same method as the synthesis of HP 1 except that a compound A-3 was fed instead of feeding the compound A-1. The number-average molecular weight (Mn) in terms of standard polystyrene determined by GPC measurement was 2,000, and the degree of dispersion of molecular weight (Mw/Mn) was 1.08. In the following reaction formula, n1 is the number of repetition of the styrene unit.

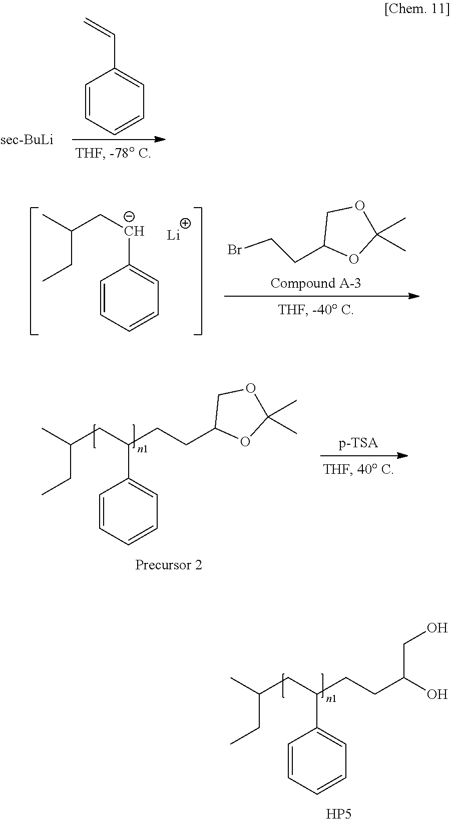

### <Homopolymer 5 (HP 5)>

Following polystyrene was used as a homopolymer 5 (HP 5). The number-average molecular weight (Mn) in terms of standard polystyrene determined by GPC measurement was 2,000. In the following reaction formula, n1 is the number of repetition of the styrene unit.

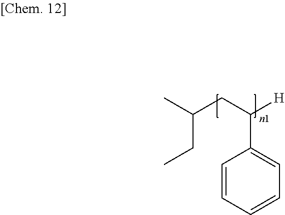

### <Measurement of Mole Ratio Between Constituent Units of Blocks>

By ¹H-NMR measurement (600 MHZ, deuterated acetone) using an NMR apparatus (manufactured by Bruker, equipped with CryoProbe), a value of integration ratio (area ratio) was measured from chemical shifts of the constituent unit of the block copolymers to calculate a mole ratio between constituent units of the blocks.

### <Preparation of Resin Composition for Forming Phase-Separated Structure and Production of Structure Having Phase-Separated Structure>

Each BCP and each HP shown in Table 1 and Table 2, and propylene glycol monomethyl ether were mixed and dissolved to prepare each of resin compositions for forming a phase-separated structure of Examples (solid-content concentration: about 1.4 mass %). Note that the addition amount refers to an addition amount (parts by mass) of HP relative to 100 parts by mass of BCP.

By using the resin compositions for forming a phase-separated structure of Examples, a structure having a phase-separated structure was formed in steps (1) to (3) described below, and subsequently a hole pattern was formed in a step (4).

Step (1): A 12-inch silicon wafer substrate was baked at 150° C. for 60 seconds. On the baked substrate, a resin composition for an undercoat agent prepared as a propylene glycol monomethyl ether acetate (PGMEA) solution at a concentration of 2 mass % (copolymer of polystyrene/polymethyl methacrylate/poly-2-hydroxyethyl methacrylate, composition ratio (mass ratio): polystyrene/polymethyl methacrylate/poly-2-hydroxyethyl methacrylate=82/12/6) was applied under a nitrogen atmosphere by using a spinner (1500 rpm), and the coating film was baked and dried at 250° C. for 300 seconds to form an undercoat agent layer with 60 nm in film thickness on the substrate.

Step (2): Subsequently, a portion in the undercoat agent layer other than the substrate adhesion portion was rinsed with a solvent OK73 thinner (manufactured by TOKYO OHKA KOGYO CO., LTD.) for 34 seconds, and then baked at 100° C. for 60 seconds. On the undercoat agent layer, the resin composition for forming a phase-separated structure of Examples was applied by spin-coating, and then soft-baked for drying at 90° C. for 60 seconds to form a resin composition layer with 43 nm in film thickness.

Step (3): This substrate was annealed at 250° C. for 15 minutes under a nitrogen atmosphere to form a phase-separated structure (cylinder structure).

Step (4): The substrate with the formed phase-separated structure was irradiated with ultraviolet ray (A: 172 nm, 160 mJ) under a nitrogen atmosphere by using CLEAN TRACK LITHIUS Pro-Z (manufactured by Tokyo Electron Ltd.). Thereafter, development was performed with isopropyl alcohol to selectively remove the phase composed of PMMA, resulting in formation of a hole pattern.

### [Evaluation of Aperture Rate]

Each of the formed hole patterns was subjected to image analysis by using an image analysis software (DSA-APPS, manufactured by Hitachi High-Tech Corporation) to determine an aperture rate (%) of each of the hole patterns. A rate at which good circular holes were formed was defined as the aperture rate, and evaluated on the following criteria. Table 1 and Table 2 show the results. Good (indicated by circle symbol (o)): More than 100% of the aperture rate of Reference Example 1 Fair (indicated by triangle symbol (Δ)): More than 97% and 100% or less of the aperture rate of Reference Example 1 Poor (indicated by cross symbol (x)): 97% or less of the aperture rate of Reference Example 1

### [Evaluation of Pitch]

Each of the formed hole patterns was subjected to image analysis by using an image analysis software (DSA-APPS, manufactured by Hitachi High-Tech Corporation) to determine an average value of pitches from each of circular holes in an image in 1350-nm square. Table 1 shows a difference from the pitch of Reference Example 1. Table 2 shows a difference from a pitch evaluated by using a resin composition for forming a phase-separated structure containing the same BCP but containing no HP. A larger difference in the pitch means a wider process margin.

TABLE 1

| | BCP | | | | Addition | | | |
|---|---|---|---|---|---|---|---|---|
| | | PS | | | amount | | Pitch | |
| | | RATIO | HP | | (parts by | Pitch | difference | Aperture |
| | Mn | (mol %) | Type | Mn | mass) | (nm) | (nm) | rate |
| Reference | 100,000 | 64 | — | — | — | 42.3 | — | — |
| Example1 | | | | | | | | |
| Example1 | 100,000 | 64 | HP1 | 2,000 | 10 | 40.1 | 2.2 | ∘ |
| Example2 | 100,000 | 64 | HP2 | 2,000 | 10 | 40.3 | 2 | ∘ |
| Example3 | 100,000 | 64 | HP3 | 2,000 | 10 | 40.2 | 2.1 | ∘ |
| Example4 | 100,000 | 64 | HP1 | 3,000 | 10 | 40.2 | 2.1 | ∘ |
| Example5 | 100,000 | 64 | HP1 | 4,000 | 10 | 40.2 | 2.1 | ∘ |
| Example6 | 100,000 | 64 | HP1 | 5,000 | 10 | 40.3 | 2 | ∘ |
| Example7 | 100,000 | 64 | HP1 | 2,000 | 20 | 39.6 | 2.7 | Δ |
| Example8 | 100,000 | 64 | HP1 | 2,000 | 30 | 39.1 | 3.2 | Δ |
| Example9 | 100,000 | 64 | HP1 | 5,000 | 30 | 39.5 | 2.8 | Δ |
| Comparative | 100,000 | 64 | HP5 | 2,000 | 10 | 41.6 | 0.7 | ∘ |
| Example1 | | | | | | | | |
| Comparative | 100,000 | 64 | HP4 | 5,000 | 30 | 40.9 | 1.4 | x |
| Example2 | | | | | | | | |

TABLE 2

| | BCP | | | | Addition | | | |
|---|---|---|---|---|---|---|---|---|
| | | PS | | | amount | | Pitch | |
| | | RATIO | HP | | (parts by | Pitch | difference | Aperture |
| | Mn | (mol %) | Type | Mn | mass) | (nm) | (nm) | rate |
| Reference | 100,000 | 64 | — | — | — | 42.3 | — | — |
| Example1 | | | | | | | | |
| Example1 | 100,000 | 64 | HP1 | 2,000 | 10 | 40.1 | 2.2 | ∘ |
| Example10 | 94,000 | 63 | HP1 | 2,000 | 10 | 39 | 2.2 | ∘ |
| Example11 | 84,000 | 63 | HP1 | 2,000 | 10 | 35.5 | 2.1 | ∘ |
| Example12 | 77,000 | 67 | HP1 | 2,000 | 10 | 31.3 | 1.9 | ∘ |
| Example13 | 61,000 | 61 | HP1 | 2,000 | 10 | 29.4 | 1.7 | ∘ |
| Example14 | 121,000 | 71 | HP1 | 2,000 | 10 | 46 | 2.3 | ∘ |
| Example15 | 143,000 | 71 | HP1 | 2,000 | 10 | 49.2 | 2.4 | ∘ |
| Comparative | 100,000 | 64 | HP5 | 2,000 | 10 | 41.6 | 0.7 | ∘ |
| Example1 | | | | | | | | |
| Comparative | 100,000 | 64 | HP4 | 5,000 | 30 | 40.9 | 1.4 | x |
| Example2 | | | | | | | | |

As shown in Table 1, it has been found that Examples using the resin composition containing the homopolymer having the predetermined structure at at least one terminal, in addition to BCP, remarkably widen the pitch difference. It has also been found that all Examples can yield the aperture rate equivalent to that of Reference Example 1. Therefore, it is understood that the resin composition for forming a phase-separated structure of Example can improve the process margin.

What is claimed is:

1. A resin composition for forming a phase-separated structure, the resin composition comprising a block copolymer and a homopolymer, wherein:
the block copolymer has a first block and a second block;
the first block and the homopolymer each independently comprise a polymer having a repeating structure of a constituent unit represented by formula (b1); and
at least one terminal of a main chain of the homopolymer has a structure I represented by formula (b2-I) or a structure II represented by formula (b2-II): 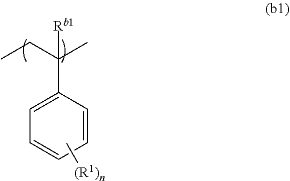
Wherein in the formula (b1), R^{b1} is a hydrogen atom or a methyl group, R¹ is an alkyl group optionally having an oxygen atom or a silicon atom, n is an integer between 0 and 5 inclusive, and when n is an integer of 2 or more, a plurality of R¹ may be same as or different from each other, 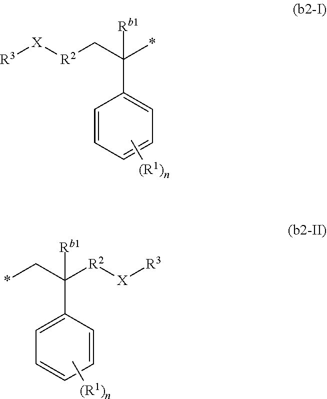
wherein in the formula (b2-I) and the formula (b2-II), R^{b1}, R¹, and n are same as those in the formula (b1), R² is an alkylene group, X is a group represented by —O—, —C(═O)—, —O—C(═O)—, or —C(═O)—O—, R³ is a hydrogen atom or a monovalent organic group, the monovalent organic group as R³ is free of a protonic acid group and is free of two or more groups represented by —Y—H, Y is a group 16 element in a periodic table, a group represented by —X—R³ is not a carboxy group, and * is a bond.

2. The resin composition for forming a phase-separated structure according to claim 1, wherein X is a group represented by —O—.

3. The resin composition for forming a phase-separated structure according to claim 1, wherein R³ is a hydrogen atom, an alkyl group, or a cyclic ether group.

4. The resin composition for forming a phase-separated structure according to claim 1, wherein an amount of the homopolymer is 1 part by mass or more and 50 parts by mass or less relative to 100 parts by mass of the block copolymer.

5. The resin composition for forming a phase-separated structure according to claim 1, wherein the block copolymer has a number-average molecular weight of 20,000 or more and 200,000 or less.

6. The resin composition for forming a phase-separated structure according to claim 1, wherein the homopolymer has a number-average molecular weight of 1,000 or more and 10,000 or less.

7. The resin composition for forming a phase-separated structure according to claim 1, wherein a proportion of a number of moles of a constituent unit of the first block to a sum of the number of moles of the constituent unit of the first block and a number of moles of the constituent unit of the second block is 20 mol % or more and 80 mol % or less.

8. A method for producing a structure having a phase-separated structure, the method comprising:
applying the resin composition for forming a phase-separated structure according to claim 1 on a support to form a layer containing a block copolymer; and
phase separating the layer containing the block copolymer.
